(19) United States
(12) Patent Application Publication
(10) Pub. No.: US 2008/0024999 A1
(43) Pub. Date: Jan. 31, 2008

(54) HOUSING FOR AN ELECTRONIC DEVICE

(75) Inventor: Chia-Chia Huang, Taipei Hsien (TW)

Correspondence Address: MCNEES WALLACE & NURICK LLC, 100 PINE STREET, P.O. BOX 1166, HARRISBURG, PA, 17108-1166, US

(73) Assignee: AOPEN INC., Taipei Hsien (TW)

(21) Appl. No.: 11/756,133

(22) Filed: May 31, 2007

(30) Foreign Application Priority Data
Jul. 26, 2006 (TW) 095127284

(51) Int. Cl. H05K 5/00

(52) U.S. Cl. 361/724

(57) ABSTRACT

A housing for an electronic device is adapted for disposition of a motherboard, a plurality of data access devices, and a plurality of cables. The housing includes a housing body and a partition plate. The housing body defines a receiving space. The partition plate is disposed in the housing body, and divides the receiving space into a first receiving compartment adapted for receiving the motherboard, and a second receiving compartment adapted for receiving the data access devices. The partition plate has a side edge cooperating with the housing body to define a wire sorting space that is in spatial communication with the first and second receiving compartments. The wire sorting space allows the cables that are connected electrically between the motherboard and the data access devices to pass therethrough. Consequently, convenience during assembly or disassembly by users or repair personnel is improved, and easier organization of the cables/wires is possible.

### CROSS-REFERENCE TO RELATED APPLICATION

This application claims priority of Taiwanese Application No. 095127284, filed on Jul. 26, 2006.

### BACKGROUND OF THE INVENTION

1. Field of the Invention

The invention relates to a housing for an electronic device, more particularly to a housing that facilitates sorting of cables/wires of the electronic device.

2. Description of the Related Art

Due to the ever increasing demand on performance capability and computing speed in computers, the configuration and arrangement of internal components in computers are becoming more complicated and more concentrated. Therefore, cables and power supply wires between the internal components are increasing in number and becoming more concentrated as well, causing inconvenience during assembly and repair of the computers. As shown in FIG. 1, a conventional computer 1 normally includes a motherboard 11 fixed uprightly to a side wall 101 of a housing 10 at an inner side of the side wall 101. An optical disk drive 12, a floppy disk drive 13, and a hard disk drive 14 are mounted horizontally to a frame rack 102 that is provided in a front portion of the housing 10. In addition, a power supply 15 is further included in the conventional computer 1 and is fixed in an upper rear portion of the housing 10.

In particular, the motherboard 11, the optical disk drive 12, the floppy disk drive 13, and the hard disk drive 14 are all disposed in a receiving space 103 of the housing 10. In order to transmit signals to the motherboard 11, the optical disk drive 12, the floppy disk drive 13, and the hard disk drive 14 are respectively connected to the motherboard 11 via cables 160, 161, 162. In addition, in order to supply electrical power needed for operation to the various components of the conventional computer 1, the power supply 15 is connected electrically to the optical disk drive 12, the floppy disk drive 13, the hard disk drive 14, and the motherboard 11 via power supply wires 150, 151, 152, respectively. Consequently, these cables 160, 161, 162 and power supply wires 150, 151, 152 often tangle with each other, making it difficult for users or repair personnel to distinguish individual cables/wires and to repair the various components in the receiving space 103 of the housing 10.

### SUMMARY OF THE INVENTION

Therefore, the object of the present invention is to provide a housing for an electronic device that facilitates sorting of cables/wires and that can be easily disassembled.

According to the present invention, there is provided a housing for an electronic device. The housing is adapted to receive a motherboard, a plurality of data access devices, a plurality of cables, and a power supply therein.

The housing includes a housing body and a partition plate. The housing body defines a receiving space. The partition plate is disposed in the housing body, and divides the receiving space into a first receiving compartment adapted for receiving the motherboard therein, and a second receiving compartment adapted for receiving the data access devices therein. The partition plate has a side edge that cooperates with the housing body to define a wire sorting space that is in spatial communication with the first and second receiving compartments. The wire sorting space is adapted to allow the cables that are connected electrically between the motherboard and the data access devices to pass therethrough.

The housing further includes a plurality of first positioning members provided on the partition plate, spaced apart from each other, disposed in the second receiving compartment, and adapted for positioning the cables. The first positioning members are L-shaped fasteners formed by stamping the partition plate, and are adapted for hooking opposite sides of the cables. The first positioning members can also be restraining belts that extend through the partition plate, and that are adapted for tying the cables.

The housing body includes abase plate, first and second side plates respectively extending in a first direction from opposite sides of the base plate, and a frame rack provided between the first and second side plates, disposed in the second receiving compartment, and adapted for receiving the data access devices therein. The housing body further includes a covering plate coupled to the first and second side plates, and disposed opposite to the base plate. The covering plate cooperates with the side edge of the partition plate to define the wire sorting space.

The partition plate extends perpendicularly from an inner side of the first side plate toward the second side plate, and abuts against the base plate. The motherboard is to be mounted to one side of the partition plate, while the frame rack is disposed on the other side of the partition plate. The frame rack includes a plate body extending perpendicularly from the inner side of the first side plate toward the second side plate, a securing rack body disposed between the plate body and the second side plate, and a first movable rack body mounted removably to the plate body and to one side of the securing rack body. The frame rack further includes a second movable rack body and a third movable rack body that are mounted removably and respectively between the first movable rack body and the first side plate. The data access devices are respectively mounted in the securing rack body, and the first, second and third movable rack bodies. The cables respectively extend between the plate body and the partition plate, and through the wire sorting space to connect electrically the data access devices and the motherboard.

The housing is further adapted to receive a power supply. The power supply includes a main body disposed between the partition plate and the second side plate, a first power supply wire connected electrically between the main body and the motherboard, and second and third power supply wires connected electrically between the main body and the data access devices. The housing further includes a plurality of second positioning members provided on the partition plate, disposed in the second receiving compartment, and adapted for positioning the second and third power supply wires.

The housing for an electronic device according to the present invention utilizes the partition plate to permit disposition of the motherboard and the data devices respectively in the first and second receiving compartments. With the addition of the first and second positioning members, the cables are positioned at the left side face of the partition plate, and can extend through the wire sorting space to be plugged into the motherboard, while the second and third power supply wires are likewise positioned at the left side face of the partition plate. Therefore, the convenience in assembling and disassembling the electronic device by users or repair personnel is enhanced, and the cables/wires are easily sorted.

### BRIEF DESCRIPTION OF THE DRAWINGS

Other features and advantages of the present invention will become apparent in the following detailed description of the preferred embodiments with reference to the accompanying drawings, of which:

FIG. 1 is a side view of a conventional computer, illustrating an internal configuration thereof;

FIG. 2 is an exploded perspective view of an electronic device incorporating the first preferred embodiment of a housing according to the present invention, illustrating a housing body of the housing that is adapted to receive first, second, third and fourth data access devices, and a power supply therein;

FIG. 3 is a perspective view of the first preferred embodiment, illustrating the housing body of the housing that is adapted to receive a motherboard, the first, second, third and fourth data access devices, and the power supply therein, with covering plates of the housing being omitted in this figure;

FIG. 4 is an exploded perspective view of the first preferred embodiment, illustrating the housing body of the housing adapted to receive the first, second, third and fourth data access devices, and the power supply therein;

FIG. 5 is a left side view of the first preferred embodiment, illustrating first, second, third and fourth flexible cables respectively positioned on a partition plate of the housing via first positioning members, and second and third power supply wires positioned on the partition plate via second positioning members, with the covering plates being omitted in this figure;

FIG. 6 is a right side view of the first preferred embodiment, illustrating the first, second, third and fourth flexible cables extending through a wire sorting space for plugging into the motherboard;

FIG. 7 is an assembled perspective view of the first preferred embodiment, with the covering plates being omitted in this figure; and

FIG. 8 is a left side view of an electronic device incorporating the second preferred embodiment of a housing according to the present invention, illustrating first, second, third and fourth flexible cables respectively positioned on a partition plate of the housing via first positioning members, and second and third power supply wires positioned on the partition plate via second positioning members, with the covering plates of the housing being omitted in this figure.

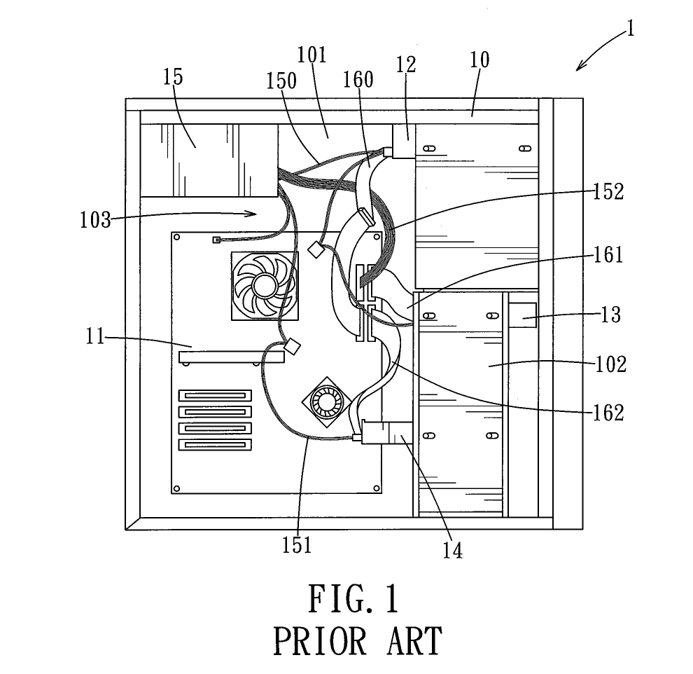

### DETAILED DESCRIPTION OF THE PREFERRED EMBODIMENTS

Before the present invention is described in greater detail, it should be noted herein that like elements are denoted by the same reference numerals throughout the disclosure.

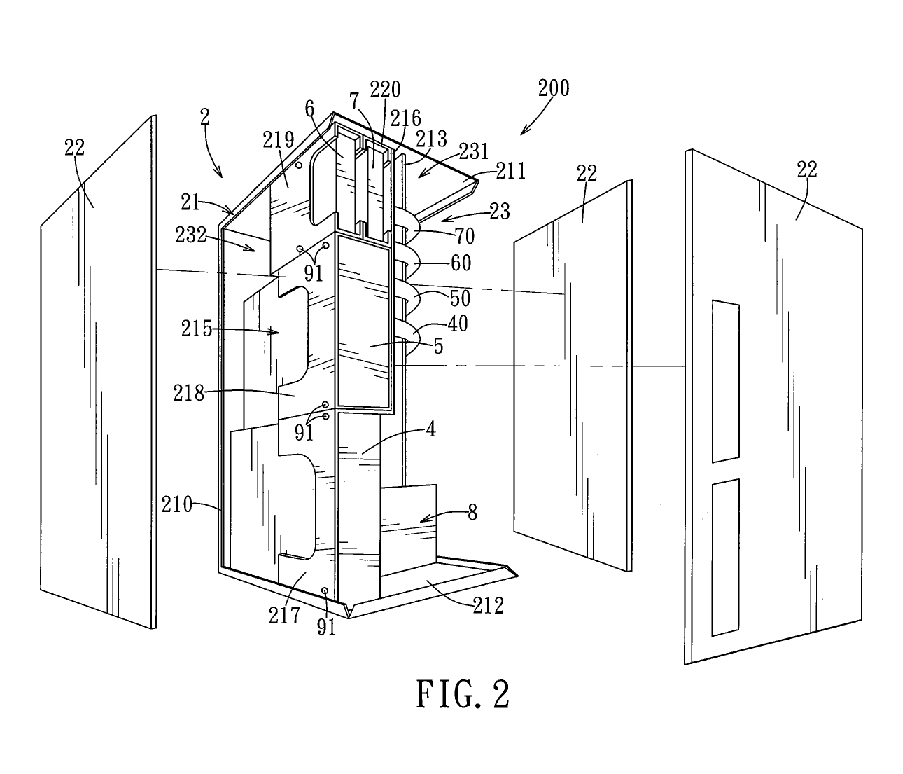

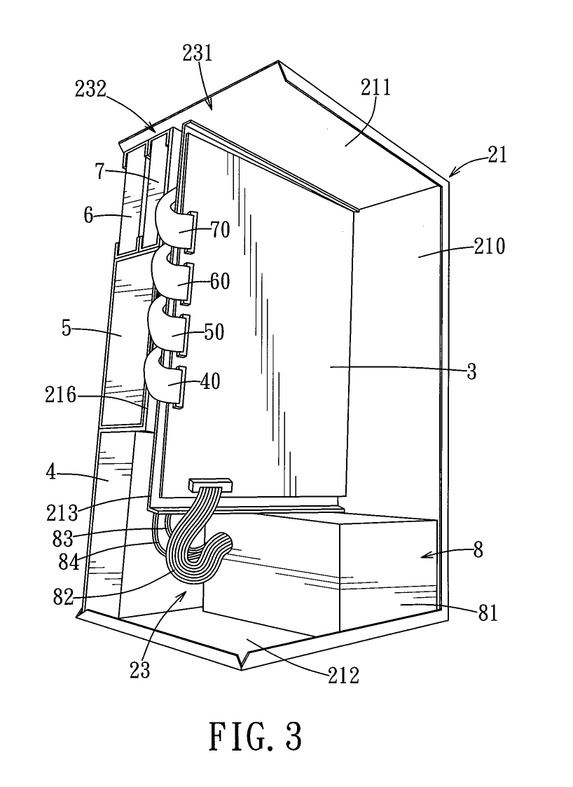

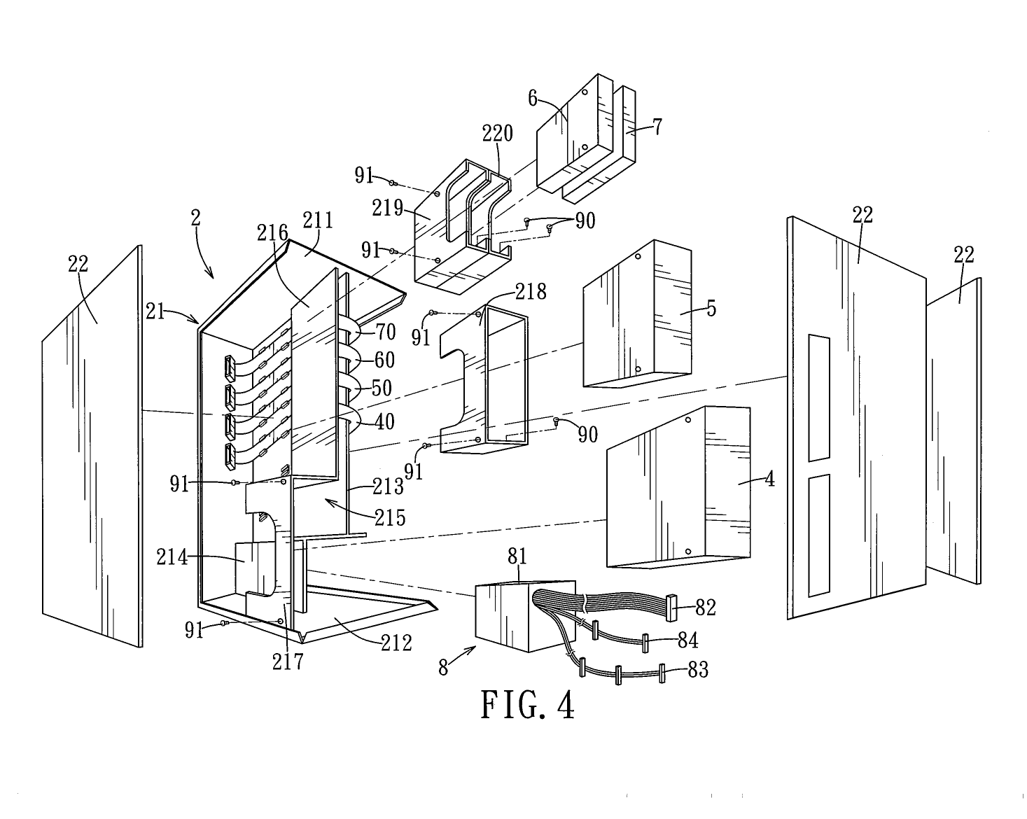

Shown in FIG. 2, FIG. 3 and FIG. 4 is an electronic device incorporating the first preferred embodiment of a housing according to the present invention. The electronic device 200 includes a tower-type housing 2, and a motherboard 3, first, second, third and fourth data access devices 4, 5, 6, 7, and a power supply 8 disposed in the housing 2. The first data access device 4 is a rewritable digital versatile disk (DVD-RW) drive, the second data access device 5 is a read-only digital versatile disk (DVD) drive, the third data access device 6 is a hard disk drive (HDD), and the fourth data access device 7 is a floppy disk drive (FDD). It should be noted herein that the housing 2 is not limited to a tower-type housing, and can be a desktop-type housing in other embodiments of the present invention.

The housing 2 is made of metal, and includes a housing body 21. The housing body 21 defines a receiving space 23 for receiving the motherboard 3, the first, second, third and fourth data access devices 4, 5, 6, 7, and the power supply 8 therein. The housing body 21 includes an upright rectangular base plate 210, first and second side plates 211, 212 respectively extending in a first direction from upper and lower sides of the base plate 210, and three covering plates 22. One of the covering plates 22 is disposed opposite to the base plate 210 and covers front sides of the first and second side plates 211, 212. The other two covering plates 22 are respectively disposed to cover left and right sides of the first and second side plates 211, 212.

The housing body 21 further includes a rectangular partition plate 213 extending perpendicularly and downwardly from a middle of a bottom side of the first side plate 211 and abutting against an inner surface of the base plate 210. The partition plate 213 divides the receiving space 23 into a first receiving compartment 231 on the right, and a second receiving compartment 232 on the left. A right surface of the partition plate 213 is adapted for mounting of the motherboard 3. In addition, a bottom edge of the partition plate 213 is spaced apart from the second side plate 212 by an appropriate distance so as to permit disposition of the power supply 8 therebetween. Moreover, the housing body 21 further includes an inverted-L-shaped limiting plate 214 provided between a bottom left side of the partition plate 213 and the second side plate 212, and abutting against the base plate 210. The limiting plate 214 is adapted to abut against the power supply 8, and to limit position of the power supply 8 after assembly of the same.

In addition, the housing body 21 further includes a frame rack 215 disposed in the second receiving compartment 232 at the left side of the partition plate 213. The frame rack 215 includes a rectangular plate body 216 extending perpendicularly and downwardly from the bottom side of the first side plate 211 proximate to a front end thereof, and spaced apart from the partition plate 213 by an appropriate distance, and a U-shaped securing rack body 217 that is provided between a lower end of the plate body 216 and the second side plate 212, and that opens to the right. The securing rack body 217 is adapted for securing the first data access device 4 therein. The frame rack 215 further includes a first movable rack body 218 mounted removably to a top side of the securing rack body 217, and disposed to the left of the plate body 216, and second and third movable rack bodies 219, 220 mounted respectively and removably between the first movable rack body 218 and the first side plate 211. Length and width of the first movable rack body 218 are both slightly longer than those of the second and third movable rack bodies 219, 220. The first movable rack body 218 is adapted for securing the second data access device 5 therein, whereas the second and third movable rack bodies 219, 220 are respectively adapted for securing the third and fourth data access devices 6, 7 therein. As shown in FIG. 2, the frame rack 215 employs a two-large-two-small configuration for disposition of the data access devices. It should be noted herein that the first movable rack body 218 can be substituted by another pair of the second and third movable rack bodies 219, 220, such that the frame rack 215 can also employ a one-large-four-small configuration for disposition of data access devices therein. In other words, the frame rack 215 is not limited to a two-large-two-small configuration.

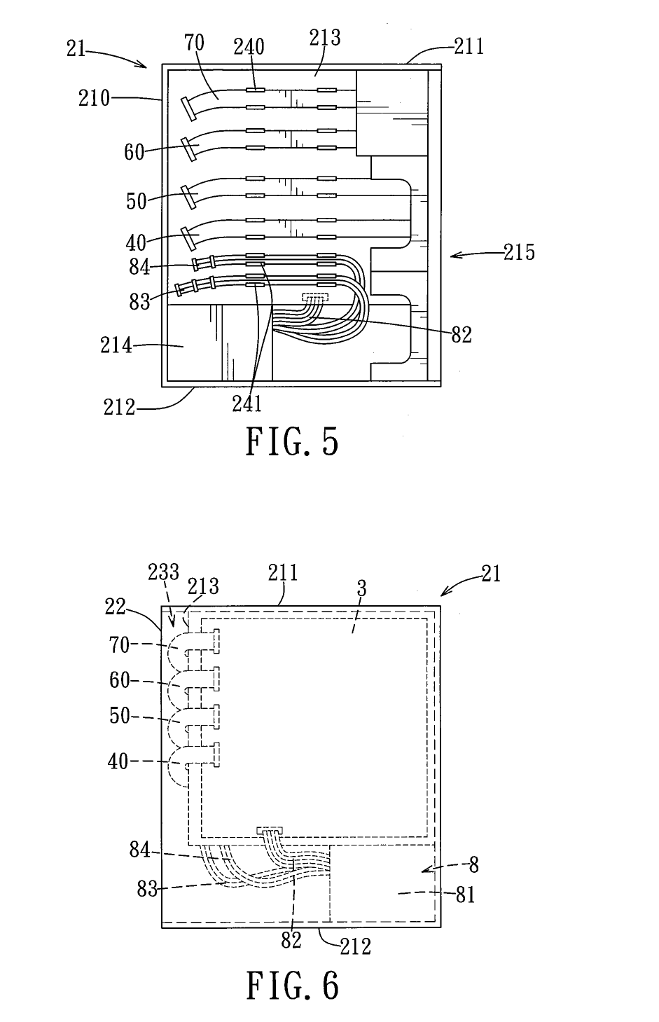

In this embodiment, a bottom surface of the first movable rack body 218 is secured to a top surface of the securing rack body 217 via a plurality of screw fasteners 90. Similarly, bottom surfaces of the second and third movable rack bodies 219, 220 are secured to a top surface of the first movable rack body 218 via screw fasteners 90. However, coupling between the first movable rack body 218 and the securing rack body 217, and that between the second and third movable rack bodies 219, 220 and the first movable rack body 218 can also employ fitting engagement involving blocks and grooves, and should not be limited to the use of the screw fasteners 90. On the other hand, the first, second, third and fourth data access devices 4, 5, 6, 7 are respectively secured to the securing rack body 217, and left surfaces of the first, second and third movable rack bodies 218, 219, 229 via a plurality of screw fasteners 91. However, couplings among these components are not limited to the use of the screw fasteners 91. As shown in FIG. 4, FIG. 5, and FIG. 6, the electronic device 200 further includes first, second, third and fourth flexible cables 40, 50, 60, 70 that are connected electrically between the motherboard 3 and the first, second, third and fourth data access devices 4, 5, 6, 7, respectively, for transmitting signals between the first, second, third and fourth data access devices 4, 5, 6, 7 and the motherboard 3. The power supply 8 includes a cubic main body 81 to be disposed between the partition plate 213 and the second side plate 212, and first, second and third power supply wires 82, 83, 84 that respectively extend from a front end of the main body 81. The first power supply wire 82 is adapted to connect the main body 81 electrically to the motherboard 3. The second power supply wire 83 is adapted to connect the main body 81 electrically to the first, second and fourth data access devices 4, 5, 7. The third power supply wire 84 is adapted to connect the main body 81 electrically to the third data access device 6.

The partition plate 213 is provided with a plurality of first positioning members 240 on the left surface of the partition plate 213. The first positioning members 240 are formed in pairs that are spaced apart from each other, are formed by stamping the partition plate 213, and are adapted for fastening upper and lower sides of the first, second, third and fourth flexible cables 40, 50, 60, 70. The partition plate 213 is further provided with a plurality of pairs of second positioning members 241 disposed below the first positioning members 240 for fastening upper and lower sides of the second and third power supply wires 83, 84. Each of the first and second positioning members 240, 241 is an L-shaped fastener in this embodiment.

Furthermore, since the front edges of the partition plate 213 and the first side plate 211 are spaced apart from each other, these front edges are not flush. When the covering plate 22 covers the front sides of the first and second side plates 211, 212, the front edge of the partition plate 213 and the covering plate 22 cooperate to define a wire sorting space 233 that is in spatial communication with the first and second receiving compartments 231, 232. The wire sorting space 233 is adapted to permit extension of the aforementioned flexible cables 40, 50, 60, 70 therethrough for plugging into the motherboard 3 that is mounted to the right surface of the partition plate 213.

As shown in FIG. 3, FIG. 4, FIG. 5 and FIG. 6, when assembling the electronic device 200, the motherboard 3 is first secured to the partition plate 213 at the right surface thereof. Then the main body 81 of the power supply 8 is brought to abut against a right side of the limiting plate 214, and is pushed rearwardly between the partition plate 213 and the second side plate 212. At the same time, the first power supply wire 82 of the power supply 8 is passed under the partition plate 213 to bring the main body 81 into electrical connection with the motherboard 3. Next, the first, second, third and fourth flexible cables 40, 50, 60, 70 are fastened to respective pairs of the first positioning members 240 that are disposed sequentially from bottom to top on the partition plate 213 such that one end of each of the cables 40, 50, 60, 70 is disposed proximate to the base plate 210. The other end of each of the cables 40, 50, 60, 70 is extended between the partition plate 213 and the plate body 216, turns at the front edge of the partition plate 213, and is plugged into the motherboard 3. On the other hand, the second and third power supply wires 83, 84 are fastened to respective pairs of the second positioning members 241 that are disposed sequentially from bottom to top on the partition plate 213 such that one end of each of the second and third power supply wires 83, 84 is disposed proximate to the base plate 210.

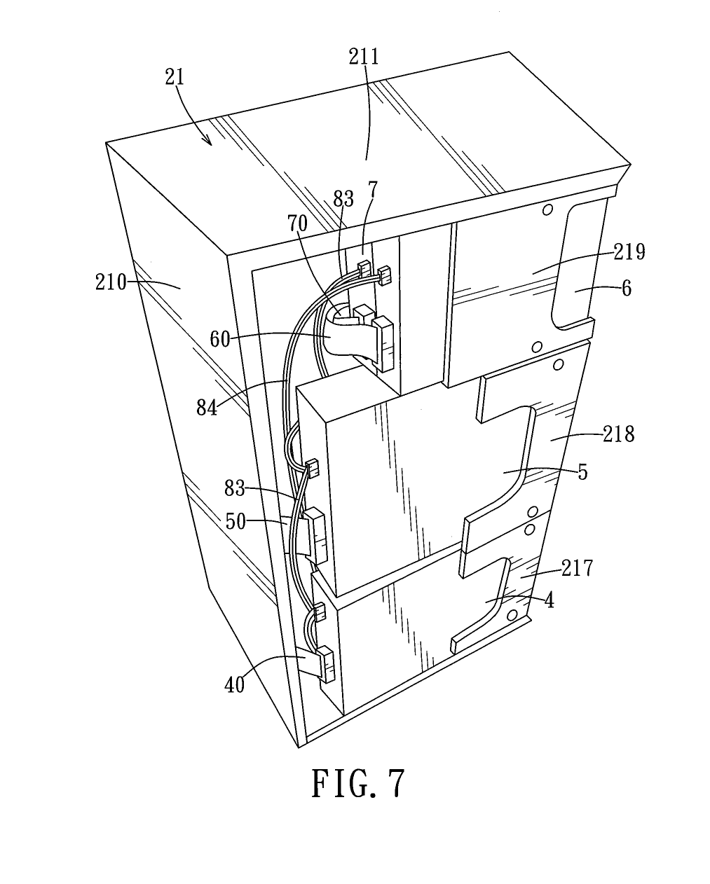

As shown in FIG. 2, FIG. 4, FIG. 5 and FIG. 7, the next step is to secure the first, second, third and fourth data access devices 4, 5, 6, 7 respectively to the securing rack body 217, and the first, second and third movable rack bodies 218, 219, 220. Afterwards, the first movable rack body 218 is secured to the top surface of the securing rack body 217, and the third and second movable rack bodies 220, 219 are then secured to the top surface of the first movable rack body 218. Subsequently, the ends of the first, second, third and fourth flexible cables 40, 50, 60, 70 that are disposed proximate to the base plate 210 are respectively plugged into rear sides of the first, second, third and fourth data access devices 4, 5, 6, 7, the second power supply wire 83 is connected electrically between the main body 81 and the first, second and fourth data access devices 4, 5, 7, and the third power supply wire 84 is connected electrically between the main body 81 and the third data access device 6. Finally, the covering plates 22 are coupled to cover the front sides, and the left and right sides of the first and second side plates 211, 212, thereby completing assembly of the electronic device 200.

By virtue of the partition plate 213 which partitions the receiving space 23 of the housing 2 into the first and second receiving compartments 231, 232 for mounting of the motherboard 3 and the first, second, third and fourth data access devices 4, 5, 6, 7, in combination with the design of the first and second positioning members 240, 241 on the partition plate 213, the first, second, third and fourth flexible cables 40, 50, 60, 70 can be secured to the left surface of the partition plate 213 in an orderly fashion, and can pass through the wire sorting space 233 for plugging into the motherboard 3, such that signals can be transmitted between the first, second, third and fourth data access devices 4, 5, 6, 7 and the motherboard 3. In addition, the second and third power supply wires 83, 84 of the power supply 8 can also be secured to the left surface of the partition plate 213 while connecting electrically the main body 81 of the power supply 8 to the first, second, third and fourth data access devices 4, 5, 6, 7. Moreover, the first power supply wire 82 of the power supply 8 is passed under the partition plate 213 to connect electrically the main body 81 and the motherboard 3. Therefore, the first, second, third and fourth flexible cables 40, 50, 60, 70 and the first, second and third power supply wires 82, 83, 84 do not tangle with each other, thereby improving the convenience during assembly and disassembly by users or repair personnel.

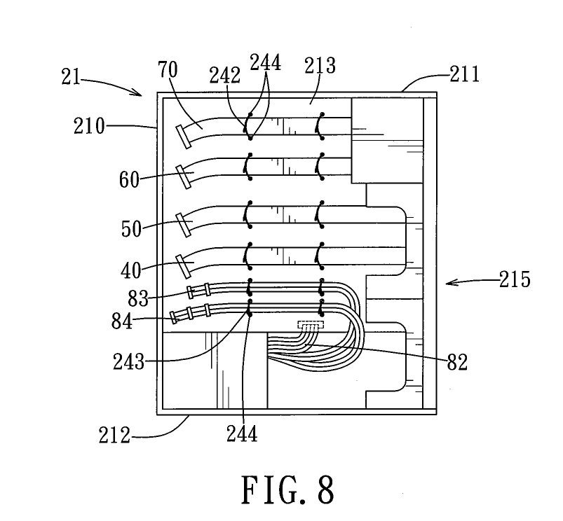

Shown in FIG. 8 is another electronic device incorporating the second preferred embodiment of a housing according to the present invention. The overall structure and the assembly procedure are generally identical to those of the first preferred embodiment, except for the structure and configuration of the first and second positioning members 242, 243. In this embodiment, each of the first and second positioning members 242, 243 is a restraining belt. Two ends of each of the first positioning members 242 extends through respective holes 244 in the partition member 213 from the first receiving compartment 231 (as shown in FIG. 3) for tying the first, second, third and fourth flexible cables 40, 50, 60, 70 to the left surface of the partition plate 213. Similarly, the second positioning members 243 also extend through the holes 244 in the partition plate 213 for tying the second and third power supply wires 83, 84 to the left surface of the partition plate 213. Thus, the first, second, third and fourth flexible cables 40, 50, 60, 70, and the second and third power supply wires 83, 84 are secured to the partition plate 213 in an orderly fashion.

In sum, in the abovementioned two embodiments, with the presence of the partition plate 213, the motherboard 3 and the first, second, third and fourth data access devices 4, 5, 6, 7 can be received in the first and second receiving compartments 231, 232. Further, with the design of the first positioning members 240, 242, the first, second, third and fourth flexible cables 40, 50, 60, 70 can be secured to the left surface of the partition plate 213 and further extend through the wire sorting space 233 for plugging into the motherboard 3. In addition, the second and third power supply wires 83, 84 are secured to the left surface of the partition plate 213 by the second positioning members 241, 243. As a result, cables/wires in the electronic device 2 are sorted in an orderly fashion, such that it is easier and more convenient to assemble and disassemble the electronic device 2 by users or repair personnel as compared to the prior art.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A housing for an electronic device that includes a motherboard, a plurality of data access devices, and a plurality of cables, said housing comprising:
a housing body defining a receiving space; and
a partition plate disposed in said housing body, and dividing said receiving space into a first receiving compartment adapted for receiving the motherboard therein, and a second receiving compartment adapted for receiving the data access devices therein, said partition plate having a side edge that cooperates with said housing body to define a wire sorting space that is in spatial communication with said first and second receiving compartments, said wire sorting space being adapted to allow the cables that are connected electrically between the motherboard and the data access devices to pass therethrough.

2. The housing as claimed in claim 1, further comprising a plurality of first positioning members provided on said partition plate, spaced apart from each other, disposed in said second receiving compartment, and adapted for positioning the cables.

3. The housing as claimed in claim 2, wherein each of said first positioning members is an L-shaped fastener formed by stamping said partition plate, said first positioning members being adapted for fastening opposite sides of the cables.

4. The housing as claimed in claim 2, wherein each of said first positioning members is a restraining belt extended through said partition plate, said first positioning members being adapted for tying the cables.

5. The housing as claimed in claim 1, wherein said housing body includes a base plate, first and second side plates respectively extending in a first direction from opposite edges of said base plate, and a frame rack provided between said first and second side plates, disposed in said second receiving compartment, and adapted for receiving the data access devices therein.

6. The housing as claimed in claim 5, wherein said partition plate extends perpendicularly from an inner side of said first side plate toward said second side plate, and abuts against said base plate, one side of said partition plate being adapted for securing the motherboard.

7. The housing as claimed in claim 6, wherein said frame rack is disposed on the other side of said partition plate, said frame rack including a plate body extending perpendicularly from said inner side of said first side plate toward said second side plate, a securing rack body disposed between said plate body and said second side plate, and a first movable rack body mounted removably to said plate body and one side of said securing rack body.

8. The housing as claimed in claim 7, wherein said frame rack further includes second and third movable rack bodies that are mounted removably and respectively between said first rack body and said first side plate.

9. The housing as claimed in claim 8, wherein said securing rack body, and said first, second and third movable rack bodies are adapted to receive the data access devices, the cables respectively extending between said plate body and said partition plate and through said wire sorting space so as to connect electrically the data access devices and the motherboard.

10. The housing as claimed in claim 6, the electronic device further including a power supply, the power supply including a main body to be disposed between said partition plate and said second side plate, a first power supply wire connected electrically between the main body and the motherboard, and a second power supply wire connected electrically between the main body and the data access devices;
wherein said housing further includes a plurality of second positioning members provided on said partition plate, disposed in said second receiving compartment, and adapted for positioning the second power supply wire.

11. The housing as claimed in claim 10, wherein each of said second positioning members is an L-shaped fastener formed by stamping said partition plate, said second positioning members being adapted for fastening opposite sides of the second power supply wire.

12. The housing as claimed in claim 10, wherein each of said second positioning members is a restraining belt extended through said partition plate, said second positioning members being adapted for tying the second power supply wire.

13. The housing as claimed in claim 5, wherein said housing body further includes a covering plate coupled to said first and second side plates and disposed opposite to said base plate, said covering plate cooperating with said side edge of said partition plate to define said wire sorting space.
